(19) United States
(12) Patent Application Publication
(10) Pub. No.: US 2026/0276451 A1
(43) Pub. Date: Sep. 17, 2026

(54) PROCESS FLOW FOR THIN CONTACTLESS THERMAL SENSORS

(71) Applicant: STMicroelectronics International N.V., Geneva (CH)

(72) Inventors: Enri DUQI, Milan (IT); Giorgio ALLEGATO, Monza (IT)

(73) Assignee: STMicroelectronics International N.V., Geneva (CH)

(21) Appl. No.: 19/680,285

(22) Filed: May 18, 2026

Related U.S. Application Data
(62) Division of application No. 18/108,154, filed on Feb. 10, 2023, now Pat. No. 12,656,179.

(51) Int. Cl. G01J 5/10; B81B 7/00; B81C 1/00

(52) U.S. Cl. CPC G01J 5/10; B81B 7/0038; B81B 7/007; B81C 1/00285; B81C 1/00301; B81B 2201/0278; B81B 2207/012; B81B 2207/07; B81B 2207/097; B81C 2203/0109; B81C 2203/0792; G01J 2005/106

(57) ABSTRACT

Disclosed herein is a method of forming a thermal sensor, including patterning an active layer on a first face of a handle substrate to form a frame, a mass carrying at least one thermally isolated MOS (TMOS) transistor, and a spring structure connecting the mass to the frame while thermally isolating the mass from the frame. The frame is then bonded to pads on a first face of an integrated circuit substrate. The handle substrate is removed, and a top cap is bonded to the first face of the integrated circuit substrate to enclose at least the mass and spring within the sealed cavity.

### RELATED APPLICATION

This application is a division of United States Application for Patent Serial No. 18/108,154, filed February 10, 2023, the content of which is incorporated by reference in its entirety.

### TECHNICAL FIELD

This disclosure is directed to the field of thermal sensing devices and, more particularly, to a process flow for forming thermally isolated MOS sensors (TMOS).

### BACKGROUND

Thermal sensors are used in a variety of devices to determine the temperature of desired targets and function by sensing infrared radiation. For example, certain types of thermal sensors can be used to determine the body temperature of a human being from a distance, while other types of thermal sensors can be used to determine the body temperature of a human being by being inserted into the ear canal.

Conventionally, thermal sensing may be performed utilizing a thermocouple. A thermocouple is formed by two junctions between two dissimilar electrical conductors – a reference junction and a sensing junction. When there is a temperature difference between the sensing junction and the reference junction, a temperature-dependent voltage is generated as a result of the Seebeck effect.

Another way thermal sensing may be performed is to use an image sensor that is sensitive to electromagnetic radiation in the infrared spectrum.

Such thermal sensors described above, however, may not have all attributes desired for certain applications. For example, such devices may not meet certain requirements regarding thickness, area, yield, and the capability to be illuminated from both the front side of the sensor and the back side of the sensor. Therefore, further development in the development of thermal sensors is still required.

### SUMMARY

Disclosed herein is a sensing device provided with a thermal sensor array, the thermal sensor array having a plurality of sub-arrays, each sub-array including an array of thermal sensors, each thermal sensor having a mass suspended over a cavity and between two sides of a frame by a plurality of springs, the mass containing a plurality of thermally isolated MOS transistors, and a reference sensor array, the reference sensor array having a plurality of sub-arrays, each sub-array including an array of reference sensors, each reference sensor having a mass suspended over a cavity and between two sides of a frame by a plurality of springs, the mass containing a plurality of thermally isolated MOS transistors, wherein each reference sensor includes a layer reflective to infrared radiation arranged over the plurality of thermally isolated MOS transistors.

In some embodiments, the thermal sensor array is used to sense ambient temperature within the sensing device in addition to an external temperature indicated by incoming infrared radiation.

In some embodiments, the reference sensor array is usable to sense ambient temperature within the sensing device such that a difference between a sum of the ambient temperature and the external temperature and the ambient temperature alone is obtained.

In some embodiments, each thermal sensor further includes an integrated circuit substrate including the cavity over which the mass is suspended, the integrated circuit substrate including conductive pads electrically coupled to the mass through the frame and the plurality of springs.

In some embodiments, the frame is bonded to the conductive pads by metallic bonds.

In some embodiments, the metallic bonds include a patterned metallic bonding layer providing electrical contact between circuitry within the integrated circuit substrate and the thermally isolated MOS transistors within the mass.

In some embodiments, each thermal sensor further includes a top cap having a cavity, the top cap being bonded to the integrated circuit substrate to enclose the mass, the plurality of springs, and the frame within a sealed chamber.

In some embodiments, the top cap is bonded to the integrated circuit substrate by a glass frit bonding layer, and the glass frit bonding layer extends between sidewalls of the top cap and the integrated circuit substrate to hermetically seal the sealed chamber.

In some embodiments, the top cap includes at least one trench formed in a sidewall, the trench being configured to receive expansion of the glass frit bonding layer.

In some embodiments, each thermal sensor further includes a getter layer disposed on an interior surface of the top cap, wherein the getter layer is positioned laterally spaced apart from the mass so as not to overlie the plurality of thermally isolated MOS transistors.

A sensing device is provided with an integrated circuit substrate including a cavity formed in a first face and a plurality of conductive pads disposed on portions of the first face external to the cavity, a frame bonded to the conductive pads, a mass suspended over the cavity, a plurality of springs extending between the frame and the mass to suspend the mass over the cavity, a plurality of thermally isolated MOS transistors disposed within the mass, and a top cap bonded to the integrated circuit substrate to form a sealed chamber enclosing the frame, the mass, and the plurality of springs.

In some embodiments, the frame is bonded to the conductive pads by a metallic bonding layer providing electrical connection between the thermally isolated MOS transistors and circuitry within the integrated circuit substrate.

In some embodiments, the top cap includes a cavity defined in a bottom face, the cavity cooperating with the cavity of the integrated circuit substrate to define the sealed chamber.

In some embodiments, sidewalls of the top cap are bonded to the integrated circuit substrate by a glass frit bonding layer.

In some embodiments, the top cap includes at least one trench formed within the sidewalls, the trench being configured to accommodate expansion of the glass frit bonding layer.

In some embodiments, the sealed chamber is maintained at a pressure substantially at vacuum.

In some embodiments, a getter layer is disposed on an interior surface of the top cap to maintain the pressure within the sealed chamber.

In some embodiments, the getter layer is positioned so as not to overlie the mass.

In some embodiments, the springs thermally isolate the mass from the frame.

In some embodiments, the integrated circuit substrate and the top cap are each formed of material transparent to infrared radiation such that infrared radiation is incident on the mass from at least one of the top cap and the integrated circuit substrate.

### BRIEF DESCRIPTION OF THE DRAWINGS

FIG. 1 is a cross-sectional view of a first embodiment of a thermal sensor disclosed herein.

FIGS. 2-5 show a process flow for forming the first embodiment of a thermal sensor disclosed herein through a series of cross-sectional views.

FIG. 6 is a cross-sectional view of the embodiment of the thermal sensor, with optional anti-reflective coatings added.

FIG. 7 is a cross-sectional view of a second embodiment of a thermal sensor disclosed herein.

FIG. 8 is a cross-sectional view of a third embodiment of a thermal sensor disclosed herein.

FIG. 9 is a diagrammatical view of a thermal sensing device including a sensing array of the thermal sensors disclosed herein as well as a reference array of the thermal sensors disclosed herein.

FIG. 10 is a greatly enlarged top view of one of the individual thermal sensor elementary cells of the sensing array of FIG. 9.

### DETAILED DESCRIPTION

The following disclosure enables a person skilled in the art to make and use the subject matter disclosed herein. The general principles described herein may be applied to embodiments and applications other than those detailed above without departing from the spirit and scope of this disclosure. This disclosure is not intended to be limited to the embodiments shown but is to be accorded the widest scope consistent with the principles and features disclosed or suggested herein.

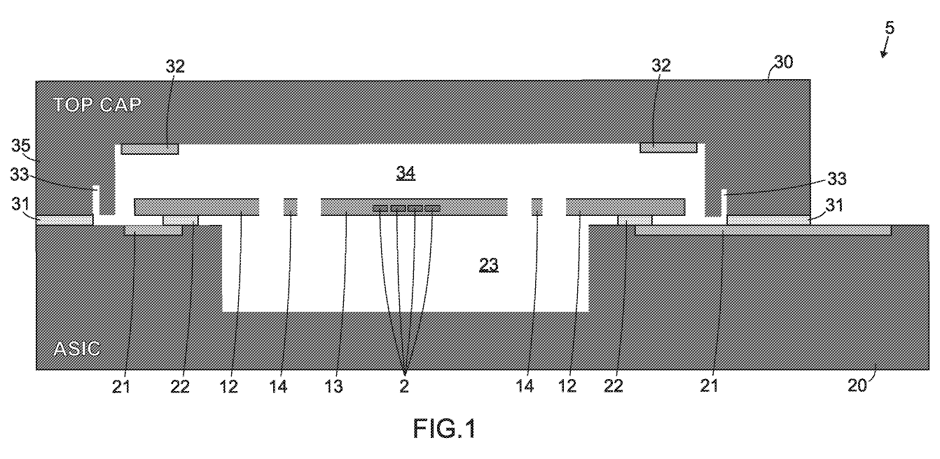

Now disclosed is a thermal sensor elementary cell 5, shown in cross section in FIG. 1 and shown in top view in FIG. 10.

The thermal sensor elementary cell 5 includes an ASIC 20 having a cavity 23 formed into the front face thereof and has conductive pads 21 on portions of its front face external to the cavity 23. The conductive pads 21 are for making electrical contact between components external to the ASIC 20 and circuitry within the ASIC 20. A frame 12 is mechanically and electrically connected to the pads 21 by metallic bonds 22. A mass 13 is suspended over the cavity 23 by springs 14 extending between the frame 12 and connection points at the perimeter of the mass 13. The mass 13 includes active area(s) 2 containing thermally isolated MOS sensors (TMOS).

Sidewalls 35 of a top cap 30 surround a cavity 34 defined within the bottom face of the top cap 30 and are hermetically sealed to the ASIC 20 over the cavity 23 by a glass frit bonding layer 31, with it being understood that the cavities 23 and 34 are in fluid communication but are environmentally sealed from the exterior of the thermal sensor elementary cell 5. Trenches 33 are formed in the sidewall 35 in a direction from the bottom face of the top cap 30 toward the back face of the top cap 30. A getter 32 is disposed on the interior surface of the top cap 30. In greater detail, the getter 32 is disposed on the floor of the cavity 34 (alternatively thought of as the roof of the cavity 34).

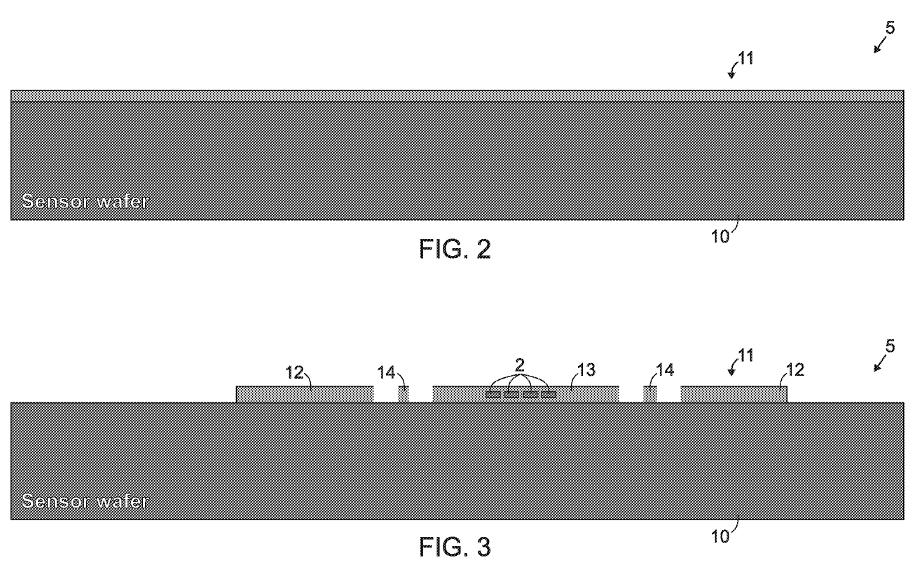

A process flow for forming the thermal sensor 5 disclosed herein (and described hereinabove) is now described with reference to FIGS. 2-5. Initially, an active layer 11 is formed on a first face of a silicon substrate 10 acting as a handle, with active area(s) 2 containing thermally isolated MOS sensors (TMOS) being formed within the active layer 11, as shown in FIG. 2. The active layer 11 is then etched to form a frame 12, a mass 13 carrying the active areas 2, and a spring 14 connecting the mass 13 to the frame 12, as shown in FIG. 3. The spring 14 serves to thermally isolate the mass 13 from the frame 12 due to the spring 14 having a low thermal conductivity. A non-metal conductive path is formed within the active layer 11 during formation thereof and extends from an exposed pad on the surface of the frame 12, through the remainder of the frame 12 to the spring 14, and through the spring to the TMOS sensors within the mass 13.

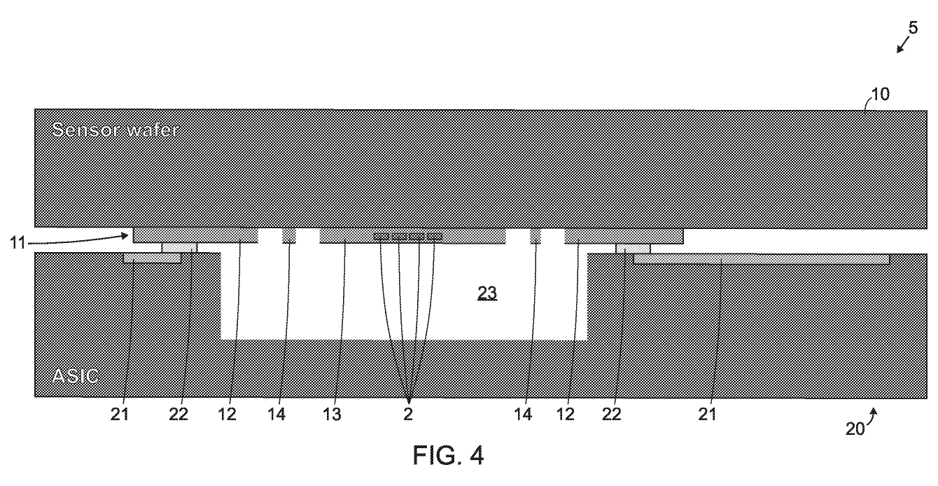

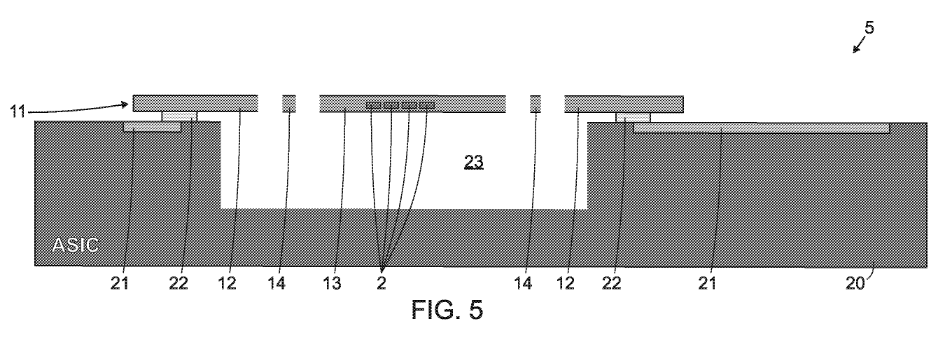

Next, the substrate 10 is flipped and its first face is bonded to the first face of an ASIC 20 formed within a silicon substrate, as shown in FIG. 4. In greater detail, the first face of the frame 12 of the active layer 11 is bonded to pads 21 on the first face of the ASIC 20 through a patterned metallic bonding layer 22 (e.g., gold or germanium), which provides for electrical contact between active components of the ASIC 20 and the above described conductive paths within the active layer 11. The substrate handle 10 is then removed, as shown in FIG. 5.

The top cap 30 is then bonded to the ASIC 20 over the frame 12, spring 14, and mass 13 through a glass frit bonding 31, as shown in FIG. 1. As explained above, the top cap has a cavity 34 formed therein, with faces of the raised sidewall 35 surrounding the perimeter of the cavity 34 being bonded to the first face of the ASIC 20 and the pads 21 (where the raised sidewall 35 overlies the pads 21) by the glass frit bonding 31.

A vacuum is present during the glass-frit bonding to achieve a vacuum within the chamber 23. Notice that a trench 33 is formed in the raised sidewall 35 of the top cap 30 to provide room for the glass frit bonding 31 to expand into during bonding without flowing onto the active layer 11, and that the trench 33 extends about the perimeter of the mass 13.

A getter layer 32 is disposed on the interior surface of the top cap 30 at positions laterally spaced apart from the mass 13. This spacing is utilized because the getter layer 32 is not transparent to infrared radiation, and therefore would obstruct infrared radiation from entering the thermal sensor 5 through the top cap 30 to reach the TMOS devices within the mass 13 if the getter layer portions were to overlie the mass 13. The getter layer 32 maintains the vacuum within the chamber 23 during operation. This completes formation of this embodiment of the thermal sensor 5.

Owing to the fact that the silicon forming the substrate 20 and top cap 30 is transparent to infrared radiation, as well as owing to the central positioning of the mass 13 containing the TMOS sensors between the sidewalls of the cavities 23 and 34 so that no components are between the mass 13 and the top cap 30 and ASIC 20, incoming infrared radiation that impinges upon the second face of the top cap 30 or the second face of the ASIC 20 can pass through to reach the TMOS sensors within the mass 13, enabling thermal sensing.

Due to the use of the substrate handle 10 to form the active layer 11, the overall thickness of the produced device 5 is less than that of prior designs, and yield is increased. In prior designs, a substrate between the top cap and ASIC carries the active layer 11. In order to achieve a desired level of thinness to meet design requirements, each of these three substrates (the ASIC, the top cap, and the substrate that carries the active layer) is thin, for example on the order of 160 microns each. With the device 5, however, because the active layer 11 is formed on the handle 10 and directly bonded to the ASIC 20 (and then the handle is removed), two substrates are present at the end (the ASIC and the top cap) – stated differently, the device 5 is formed by the top cap and ASIC, with the active layer 11 carried between the cavities 23 and 34, without an intervening substrate carrying the active layer 11. This permits the ASIC 20 and top cap 30 to be thicker than in previous designs, for example on the order of 250 microns, greatly increasing robustness and in turn reducing damage during fabrication to increase the yield.

Additionally, in prior designs utilizing the three substrates (the ASIC, the top cap, and the substrate that carries the active layer), there are two glass frit bonds performed, one between the ASIC and the substrate that carries the active layer, and one between the substrate that carries the active layer and the top cap. The coefficient of thermal expansion of the glass material is not matched to that of silicon, leading to mechanical stresses on the device. Since the prior design utilizes two glass frit bonds, it undergoes additional mechanical stresses as compared to the design described herein which utilizes a single glass frit bond. This adds to robustness and helps eliminate or reduce warping of the device.

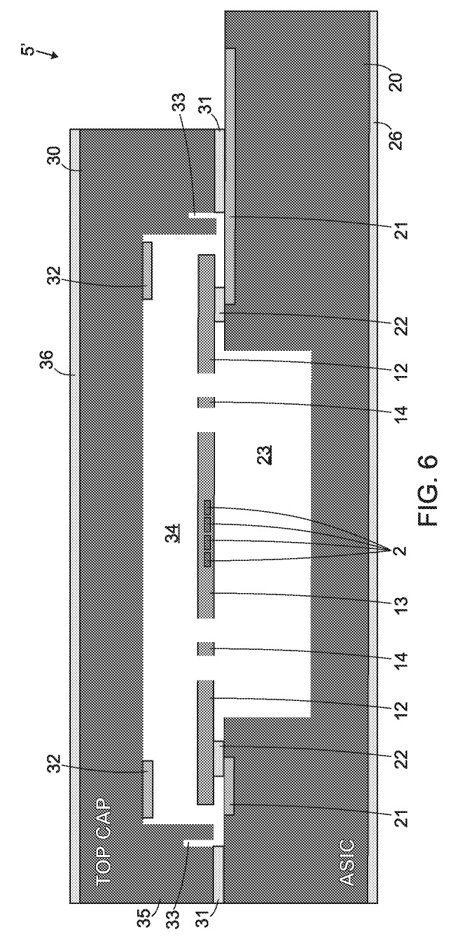

An anti-reflective coating 36 may be formed on the second side of the top cap 30, and similarly an anti-reflective coating 26 may be formed on the second side of the ASIC 20, as shown in FIG. 6. The anti-reflective coatings 26 and 36 serve to help ensure that incident infrared radiation does not reflect off the second side of the top cap 30 or the second side of the ASIC 20. Both anti-reflective coatings 26 and 36 need not be present, and instead only one may be present, depending upon application.

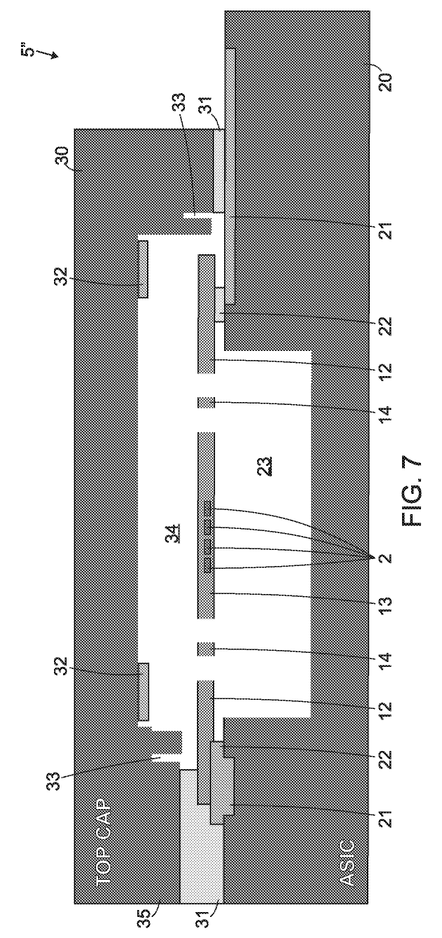

In an alternative embodiment shown in FIG. 7, the glass frit bonding 31 may extend over a portion of the frame 12.

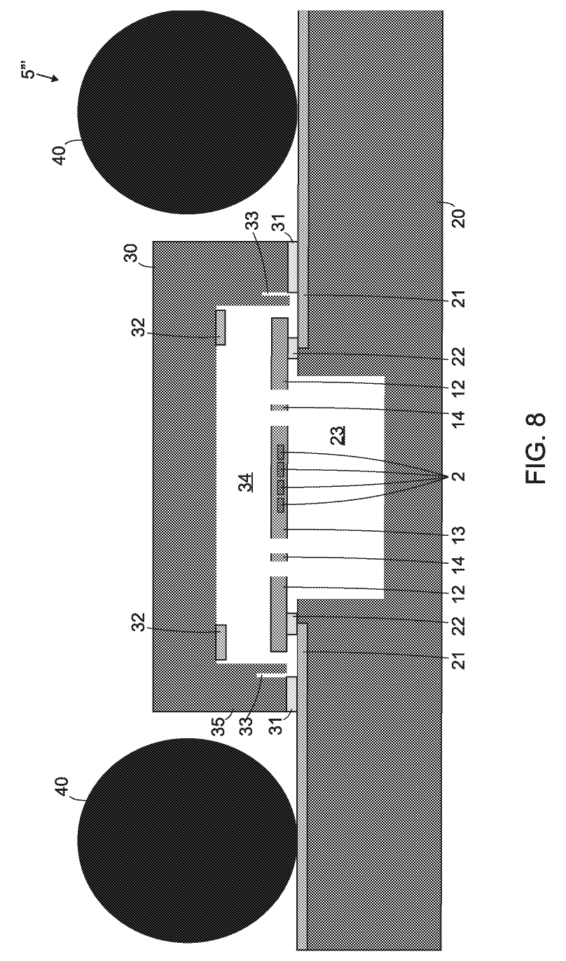

In another alternative embodiment shown in FIG. 8, the pads 21 extend farther along the first side of the ASIC 20 and solder balls 40 are connected to the pads 21 external to the cap 30.

As to external connections being made to the thermal sensor 5 in the embodiments of FIGS. 5-7, exposed portions of the pads 21 may be connected to external components via wire bonding.

As will be appreciated by those of skill in the art, the thermal sensors described above may be formed at the wafer level into arrays of such thermal sensors, and multiple such arrays may be used to form a single device.

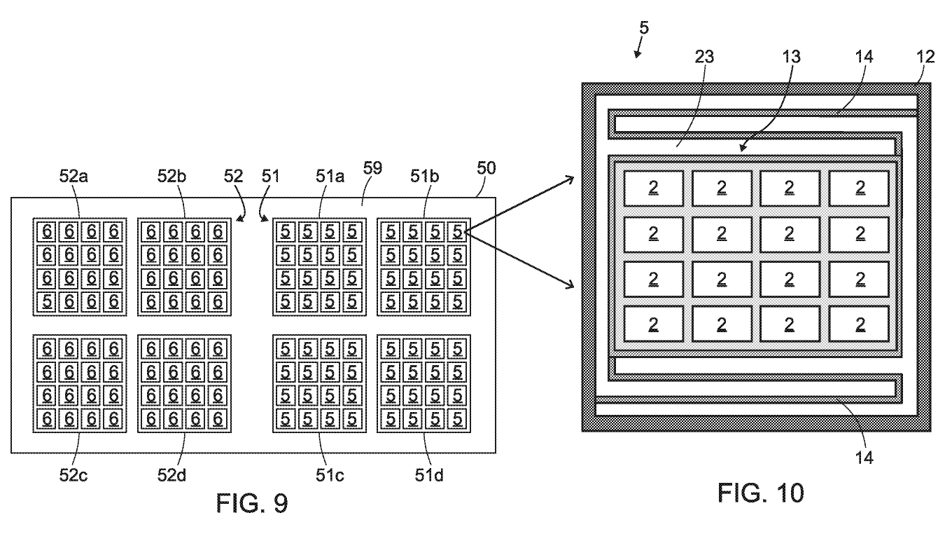

See, for example, FIG. 9, showing a single sensing device 50 with a first array 51 of thermal sensors 5 as described above and a second array 52 of reference sensors 5 identical to the thermal sensors described above but covered by material that is not transparent to infrared sensing. Therefore, the array 51 of thermal sensors 5 is used to sense ambient temperature within the device 50 in addition to the temperature/wavelength of incoming infrared radiation while the array 52 of reference sensors 6 is used to sense ambient temperature within the device 50. The difference between the ambient+incoming temperature sensed by the array 51 and the ambient temperature sensed by the array 52 yields the temperature to be sensed.

As to specific structure, the first array 51 includes four sub-arrays 51a-51d carried by a device frame 59. Wide portions of the device frame 59 space the sub-arrays 51a-51d apart from one another. Each sub-array 51a-51d itself includes an array of thermal sensor elementary cells 5, the thermal sensor elementary cells 5 being those described above and each including a frame 12, a mass 13 containing an array of TMOS transistors 2, and springs 14 connected between the frame 12 and mass 13 to suspend the mass 13 over the cavity 23. Within each sub-array 51a-51d, its pixels 5 are separated from one another by narrow frame portions.

The second array 52 includes four sub-arrays 52a-52d carried by a device frame 59. Wide portions of the device frame 59 space the sub-arrays 52a-52d apart from one another. Each sub-array 52a-52d itself includes an array of reference sensors 6, such as those described above.

Modifications and variations may be made to what has been described and illustrated herein, without thereby departing from the scope of this disclosure, as defined in the annexed claims.

While the disclosure has been described with respect to a limited number of embodiments, those skilled in the art, having benefit of this disclosure, will appreciate that other embodiments can be envisioned that do not depart from the scope of the disclosure as disclosed herein. Accordingly, the scope of the disclosure shall be limited only by the attached claims.

1. A sensing device, comprising:
a thermal sensor array comprising a plurality of thermal sensor sub-arrays, each including an array of thermal sensors, each thermal sensor comprising a thermal mass suspended over a thermal cavity and between two sides of a first frame by a plurality of springs, the thermal mass containing a first plurality of thermally isolated MOS (TMOS) transistors; and
a reference sensor array comprising a plurality of reference sensor sub-arrays, each including an array of reference sensors, each reference sensor comprising a reference mass suspended over a reference cavity and between two sides of a second frame by a plurality of springs, the reference mass containing a second plurality of thermally isolated MOS (TMOS) transistors, wherein each reference sensor includes a layer reflective to infrared radiation arranged over the second plurality of TMOS transistors.

2. The sensing device of claim 1, wherein the thermal sensor array is used to sense ambient temperature within the sensing device in addition to an external temperature due to incoming infrared radiation.

3. The sensing device of claim 2, wherein the reference sensor array is usable to sense ambient temperature within the sensing device such that a difference between a sum of the ambient temperature and the external temperature as sensed by the thermal sensor array and the ambient temperature alone as sensed by the reference sensor array yields the ambient temperature.

4. The sensing device of claim 1, wherein each thermal sensor further comprises an integrated circuit substrate including the thermal cavity over which the thermal mass is suspended, the integrated circuit substrate including conductive pads electrically coupled to the thermal mass through the first frame and the associated plurality of springs.

5. The sensing device of claim 4, wherein the first frame is bonded to the conductive pads by metallic bonds.

6. The sensing device of claim 5, wherein the metallic bonds comprise a patterned metallic bonding layer providing electrical contact between circuitry within the integrated circuit substrate and the TMOS transistors within the thermal mass.

7. The sensing device of claim 4, wherein each thermal sensor further comprises a top cap having a top cavity, the top cap being bonded to the integrated circuit substrate to enclose the thermal mass, the associated plurality of springs, and the first frame within a sealed chamber.

8. The sensing device of claim 7, wherein the top cap is bonded to the integrated circuit substrate by a glass frit bonding layer; and wherein the glass frit bonding layer extends between sidewalls of the top cap and the integrated circuit substrate to hermetically seal the sealed chamber.

9. The sensing device of claim 8, wherein the top cap includes at least one trench formed in a sidewall thereof, the at least one trench being configured to receive expansion of the glass frit bonding layer.

10. The sensing device of claim 7, wherein each thermal sensor further comprises a getter layer disposed on an interior surface of the top cap; wherein the getter layer is positioned laterally spaced apart from the thermal mass so as not to overlie the plurality of TMOS transistors.

11. A sensing device, comprising:
an integrated circuit substrate including a cavity formed in a first face thereof and a plurality of conductive pads disposed on portions of the first face external to the cavity;
a frame bonded to the conductive pads;
a mass suspended over the cavity;
a plurality of springs extending between the frame and the mass to suspend the mass over the cavity;
a plurality of thermally isolated MOS transistors disposed within the mass; and
a top cap bonded to the integrated circuit substrate to form within the cavity a sealed chamber enclosing the frame, the mass, and the plurality of springs.

12. The sensing device of claim 11, wherein the frame is bonded to the conductive pads by a metallic bonding layer providing electrical connection between the thermally isolated MOS transistors and circuitry within the integrated circuit substrate.

13. The sensing device of claim 11, wherein the top cap includes a top cavity defined in a bottom face thereof, the top cavity cooperating with the cavity of the integrated circuit substrate to define the sealed chamber.

14. The sensing device of claim 13, wherein sidewalls of the top cap are bonded to the integrated circuit substrate by a glass frit bonding layer.

15. The sensing device of claim 14, wherein the top cap includes at least one trench formed within the sidewalls, the at least one trench configured to accommodate expansion of the glass frit bonding layer.

16. The sensing device of claim 13, wherein the sealed chamber is maintained at a pressure substantially at vacuum.

17. The sensing device of claim 16, further comprising a getter layer disposed on an interior surface of the top cap to maintain the pressure within the sealed chamber.

18. The sensing device of claim 17, wherein the getter layer is positioned so as not to overlie the mass.

19. The sensing device of claim 11, wherein the plurality of springs thermally isolate the mass from the frame.

20. The sensing device of claim 11, wherein the integrated circuit substrate and the top cap are each formed of material transparent to infrared radiation such that infrared radiation is incident on the mass from at least one of the top cap and the integrated circuit substrate.
